(19) United States
(12) Patent Application Publication
(10) Pub. No.: US 2025/0246431 A1
(43) Pub. Date: Jul. 31, 2025

(54) INTEGRATED CIRCUIT (IC) WITH CORRUGATED CHANNEL STRUCTURES HAVING CONTROLLED DOPING PROFILE OVER CHANNEL TOPOGRAPHY BASED ON DOPANT BALANCING OXIDATION

(71) Applicant: TEXAS INSTRUMENTS INCORPORATED, Dallas, TX (US)

(72) Inventors: Brian Ellingwood, Millcreek, UT (US); Christopher Thompson, Salt Lake City, UT (US); Robert Cassel, Lehi, UT (US); Jackson Bauer, Rowlett, TX (US); Sheldon Douglas Haynie, Dallas, TX (US)

(21) Appl. No.: 18/428,212

(22) Filed: Jan. 31, 2024

(51) Int. Cl. H01L 21/225; H01L 21/02; H01L 21/311; H01L 21/8234

(52) U.S. Cl. CPC H01L 21/2253; H01L 21/02129; H01L 21/31111; H10D 84/0158; H10D 84/038

(57) ABSTRACT

An integrated circuit (IC) device including one or more corrugated channel structures formed in or over a semiconductor substrate, where a corrugated channel structure includes modified first and second sidewalls and a modified top surface. In an example, the corrugated channel structure is provided with a substantially uniform distribution profile of a dopant across a horizontal plane from the modified first sidewall to the modified second sidewall.

### FIELD OF THE DISCLOSURE

Disclosed implementations relate generally to the field of integrated circuits (ICs) and IC fabrication. More particularly, but not exclusively, the disclosed implementations relate to an IC device including one or more corrugated channel structures.

### BACKGROUND

FinFETs are a type of three-dimensional (3D) MOSFET transistor where the channel includes a non-planar structure resembling a “fin” and comprises semiconductor material protruding from a semiconductor substrate. FinFETs are regarded as candidates for use in future advanced CMOS technology nodes due to the FinFET's superior gate control over the channel, resulting in faster switching times, improved short-channel effect immunity, higher current densities, and improved Iₒₙ/I_{off} ratios. As the integration of FinFET technologies continues to become more prevalent, demands for improvements in various aspects of the FinFET design are increasing.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to an IC device and its fabrication, where the IC device may include one or more corrugated channel structures formed in or over a semiconductor substrate. Each corrugated channel structure may include a first sidewall, a second sidewall and a top surface. In an example, the corrugated channel structure is provided with a substantially uniform distribution profile of a dopant over the channel topography facilitated by dopant balancing oxidation and subsequent removal of oxidized material.

In one example, a method of fabricating an IC device is disclosed. The method may comprise, among others, forming a corrugated channel structure over a semiconductor substrate, the corrugated channel structure including a sidewall and a top surface; implanting a dopant in the top surface, thereby forming an upper doped region having a first dopant concentration at the top surface; oxidizing the upper doped region; and removing the oxidized upper doped region, thereby forming a modified top surface having a modified dopant concentration at the modified top surface, the modified dopant concentration being lower than the first dopant concentration.

In one example, a method of fabricating an IC device is disclosed. The method may comprise, among others, forming a plurality of corrugated channel structures over a semiconductor substrate, where the corrugated channel structures may be separated by respective trenches formed between adjacent corrugated channel structures, each trench including a bottom surface and each corrugated channel structure including a first sidewall, a second sidewall and a top surface; implanting a dopant in the first sidewalls, the second sidewalls and the top surfaces of the respective corrugated channel structures and in the bottom surfaces of the respective trenches, thereby forming an outer doped layer having a dopant concentration higher than a target dopant concentration; oxidizing the outer doped layer; and removing the oxidized outer doped layer, thereby forming modified first sidewalls, modified second sidewalls and modified top surfaces of the respective corrugated channel structures and modified bottom surfaces of the respective trenches. In some arrangements, the oxidized outer doped layer may be removed in a wet etch process involving HF. In some arrangements, the first and second sidewalls and the top surfaces of the respective corrugated channel structures and the bottom surfaces of the respective trenches may be implanted using one or more beamline implants. In some arrangements, the first and second sidewalls and the top surfaces of the respective corrugated channel structures and the bottom surfaces of the respective trenches may be implanted using one or more plasma-assisted doping (PLAD) implants. In some arrangements, the outer doped layer may be comprised of continuously connected horizontal portions formed at the top surfaces and the bottom surfaces, with vertical portions formed in the respective sidewalls disposed therebetween, where the horizontal portions and the vertical portions may be oxidized at different rates based on the dopant concentrations in respective horizontal and vertical portions.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described. Shapes depicted in the drawings attached are simplified for ease of drafting and/or presentation and support of concepts. They do not limit the scope of examples of the present disclosure with respect to size, count, aspect ratio, contour or specific angles and radii of transitions and/or other related features that may be present in an example implementation.

Terms describing a method of construction such as an “implant” and its derivatives are examples and do not reflect all methods of doping the semiconductor material in an example implementation, which could include vapor or gas phase, solid source, liquid source as well as plasma and beamline implant, depending on implementation. Alternative methods are likely and may be used as appropriate in additional and/or alternative arrangements depending on performance, costs and availability, and the like.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1A-1C depict aspects and features of an IC device including one or more corrugated channel structures where dopants may be introduced according to some examples of the present disclosure;

FIGS. 2A-2C depict additional aspects and features of an IC device including one or more corrugated channel structures where dopants may be introduced according to some examples of the present disclosure;

FIGS. 3A-3D are flowcharts of IC fabrication methods for conformally doping the corrugated channel structures of an IC device according to some examples of the present disclosure;

FIGS. 4A-1/4A-2 to FIG. 4D depict cross-sectional views of an IC device at various stages of formation for fabricating conformally doped corrugated channel structures according to an example of the present disclosure; and

FIG. 5 depicts a simulated dopant profile across a corrugated channel structure according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of IC devices comprising one or more corrugated channel structures and the fabrication thereof will be set forth below in the context of a process flow that includes line-of-sight implantation techniques, e.g., using beamline ion implant systems.

It is desirable that dopant levels across the channel structures having a vertical topography, also referred to herein as corrugated channel structures or fins, have uniform distributions so that the electrical and other performance characteristics of an IC device including the channel structures are better controlled. By way of example, fin-based devices having source/drain extensions such as drain extended metal oxide semiconductor (DEMOS) field effect transistor (FET) devices, laterally diffused MOS (LDMOS) devices, etc., generally require relatively uniform doping levels across various portions of the fin (e.g., across a top portion, a bottom portion and between the two sidewalls forming lateral portions of the fin) for acceptable threshold voltage control and to prevent impact ionization in more heavily doped regions that can be caused by hot carrier phenomena.

FinFETs may also exhibit susceptibility to performance trade-offs such as on-resistance (Rₛₚ) vs. safe operating area (SOA), where SOA may be defined as the voltage and current conditions over which the device can be expected to operate without damage, which in turn may be related to the breakdown voltage of the device, BVDSS. Further, FinFETs are also afflicted with parasitic bipolar effects that may impact the device operation. In both these conditions, it is expected that potential adverse effects may be mitigated by providing more uniform dopant distribution profiles across the topography of the corrugated channel structures.

Beamline ion implant systems based on line-of-sight (LOS) implantation techniques are often used in introducing dopants into various portions of an IC device. A beamline implant in a fin device typically results in higher doping levels at the top of the fin relative to the bottom and sidewalls due to shadowing of the fin bottom and sidewalls by an adjacent fin. The higher doping at the top of the fin occurs because in implanting each side of the fin, the top surface is implanted twice, thereby causing double dosing, which can hinder obtaining uniform levels of dopant distribution in the fins. Moreover, the bottom surfaces of the trenches between the adjacent fins may also be implanted twice depending on the form factors of the fins, sizing/spacing of the trenches, incident angles of the implant, etc., thereby further exacerbating the dopant distribution profiles in the fins and surrounding regions in the device.

Some implant techniques that do not involve line-of-sight implanting, such as plasma-assisted doping (PLAD) or atomic layer deposition (ALD) doping, may be employed in a fabrication flow in an attempt to achieve more uniform dopant distributions in the fin-based devices. Additional methods to obtain uniform dopant profiles may include forming epitaxial silicon with in-situ doping. However, such techniques are generally more expensive, thus adding to manufacturing costs.

Examples of the present disclosure recognize these and other related deficiencies and provide a fabrication flow including dopant balancing oxidation and subsequent removal of oxidized dopant material for achieving a more uniform dopant distribution profiles over the corrugated channel topography. In some arrangements, dopants may be introduced into the corrugated channels using a variety of implant techniques, including LOS-based and/or non-LOS implant techniques, where a balancing oxidation process may be configured to consume more heavily doped regions that may be subsequently removed in order to obtain target dopant concentrations and junction depths. Accordingly, the detrimental effects of double dosing and/or uneven dosing of the fin structures caused in the baseline implant techniques may be avoided or reduced even in high aspect ratio vertical topographies. While such examples provide materials and processes that advantageously allow cost-effective integration of beamline implanting techniques in a FinFET fabrication flow, no particular result is a requirement unless explicitly recited in a particular claim.

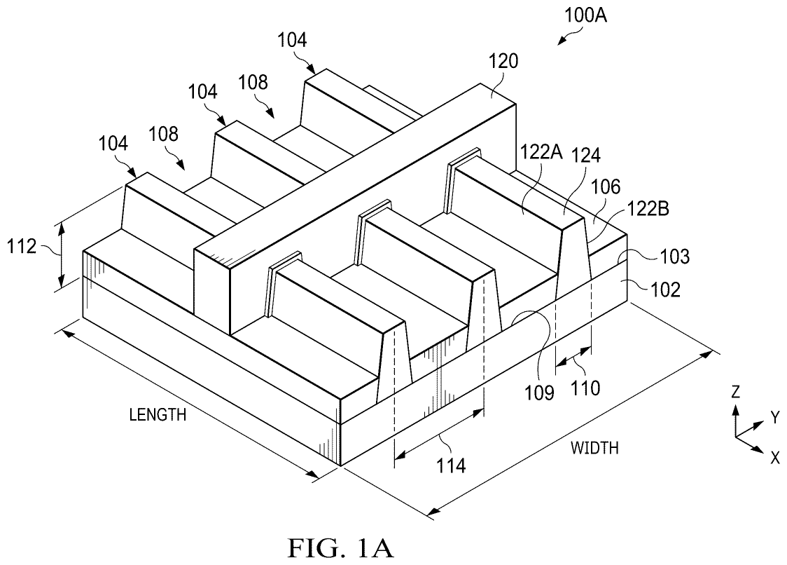

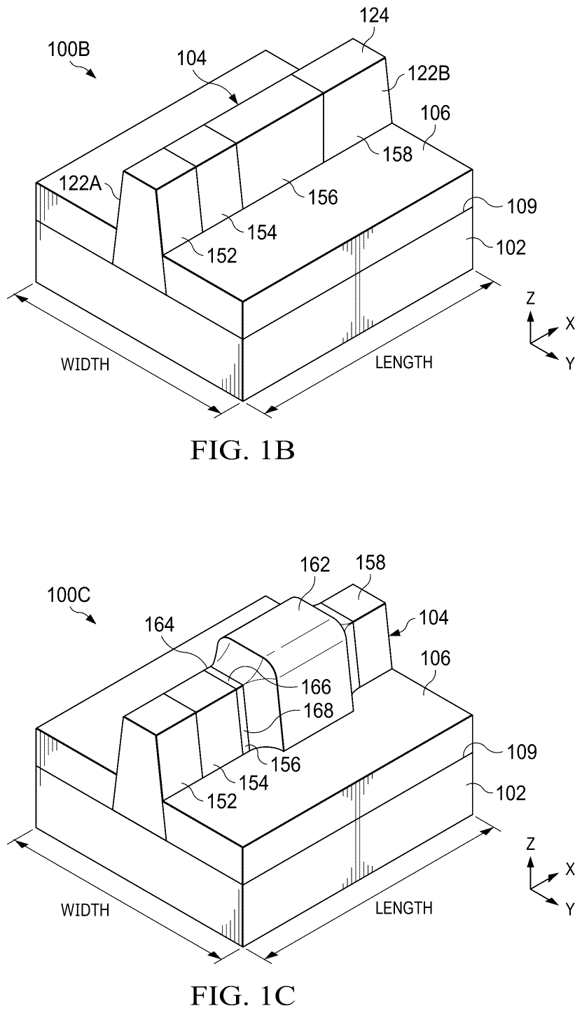

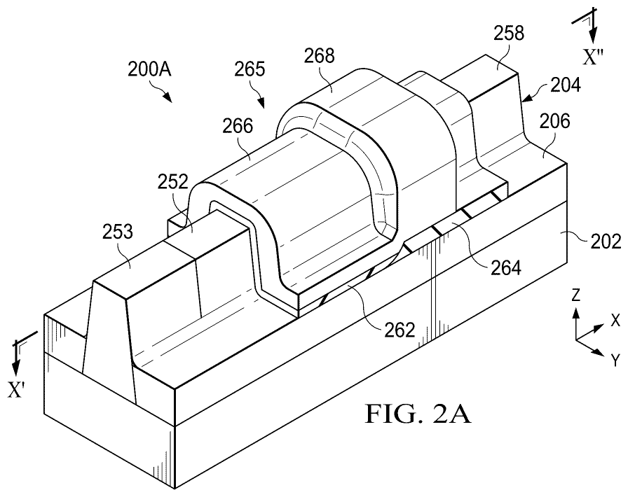

Referring now to the drawing Figures, FIGS. 1A-1C depict various aspects and features of an IC device including one or more corrugated channel structures where dopants may be introduced according to some examples of the present disclosure. In particular, FIG. 1A depicts a 3-dimensional perspective view of an IC device 100A including a plurality of corrugated channel structures 104, or “fins”, separated by trenches 108 formed between the adjacent corrugated channel structures 104. According to examples set forth in further detail below, different portions or regions of the corrugated channel structures 104 and the trenches 108 may be implanted with one or more dopants using any baseline techniques, e.g., line-of-sight (LOS) and non-LOS implant techniques, followed by a dopant balancing oxidation process for selectively oxidizing doped regions having dopant concentrations different than target dopant concentrations and removing such oxidized dopant regions so as to achieve more uniform dopant distributions. Depending on implementation and application, the example IC device 100A may be representative of any type of standalone FinFET device or a portion of an integrated microelectronic device including one or more FinFETs integrated with various other types of circuitry. In some arrangements, the IC device 100A or at least a portion thereof may be illustrative of devices such as, including but not limited to folded DEMOS devices, LDMOS FinFET devices, and FinFETs configured for high voltage power applications (e.g., having appropriate breakdown voltage (V_{bd}) and specific on-resistance (Rₛₚ) characteristics suitable for operating voltage ranges of 5V to 50V or more), low voltage logic applications, high voltage radio frequency (RF) applications, etc. Further, the IC device 100A may be fabricated in a silicon or other semiconductor material as noted below, e.g., as a bulk FinFET, epitaxial FinFET, silicon-on-insulator (SOI) FinFET, etc., depending on implementation and/or application.

As illustrated, the corrugated channel structures 104 may be formed in a semiconductor substrate 102 or a region of the substrate 102 of the IC device 100A, which may comprise any suitable semiconductor material having appropriate conductivity type (e.g., in a bulk material or in a well region, etc.). In disclosed examples, the semiconductor substrate material may have a first conductivity type, e.g., p-type. Each corrugated channel structure 104 includes a top surface 124, a first sidewall 122A and a second sidewall 122B, and may be separated from adjacent corrugated channel structures 104 by trenches 108 having a bottom surface 109. In some examples, the trenches 108 may be formed by a suitable anisotropic etch, e.g., reactive ion etch (RIE) process using fluorine radicals, in association with appropriately patterned masking. By way of example, the trenches 108 may have an average depth of 300 nanometers (nm) to 1200 nm or more, which corresponds to an average vertical height 112 of the corrugated channel structures 104 in a Z-direction along a surface normal relative to a top major surface, e.g., surface 103, of the semiconductor substrate 102 after the formation of the corrugated channel structures 104. Depending on design rules, the corrugated channel structures 104 may repeat along the Y direction with a pitch distance 114. In some arrangements, the sidewalls 122A, 122B of the corrugated channel structures 104 may be slanted or angled such that the respective corrugated channel structure 104 may be formed as a tapered structure where an upper portion including the top surface 124 may have a width that is about 40% to 50% of the height 112 of the corrugated channel structure 104. In some arrangements, a lower portion of the corrugated channel structure 104 may have a width 110 that is about 50% to 60% of the height 112 of the corrugated channel structure 104. Accordingly, the sidewalls 122A, 122B may comprise slanted surfaces having angles of around 80° to 89° with respect to a horizontal surface, e.g., the bottom surface 109 of the trenches 108 and/or the top major surface 103, in some examples. Further, representative heights 112, widths 110 and pitches 114 associated with the plurality of corrugated channel structures 104 may be varied, e.g., generally or individually, including taking into account appropriate process bias(es) needed for achieving target dimensions of the corrugated channel structures 104 subsequent to the removal of oxidized material pursuant to dopant balancing oxidation. Whereas the depth of the trenches 108 is usually consistent, it may vary with trench width in some examples. Sidewall angles and shapes may vary from the examples shown in the drawing Figures and may be optimized for different process/device attributes.

In some arrangements, the IC device 100A may include an isolation structure 106 formed over the substrate 102 for providing dielectric isolation with respect to an electrode structure 120 formed over the corrugated channel structures 104. In some arrangements, the isolation structure 106 may be formed in a shallow trench isolation (STI) process, which may include depositing a dielectric material, such as silicon dioxide, on the substrate 102 to fill a trench space about the corrugated channel structures 104 and etching the dielectric material to a desired thickness, thereby exposing a desired vertical topography of the corrugated channel structures 104. In some arrangements, the electrode structure 120 may comprise a polysilicon gate isolated from the corrugated channel structures 104 by a suitable gate oxide. Depending on operating voltage requirements, e.g., in high voltage applications involving voltages >5V, an optional thick oxide layer may be provided, which may be operable as a field plate oxide (not shown in this Figure) formed over the corrugated channel structures 104.

FIGS. 1B and 1C depict portions 100B and 100C, respectively, of the IC device 100A, where an example corrugated channel structure 104 is shown with additional details or features according to some examples. As illustrated in FIG. 1B, the corrugated channel structure 104 may comprise multiple regions or portions, e.g., a source region 152, a body region 154, a drift region 156 and a drain region 158, which may be formed by introducing suitable dopant species into selected regions of the corrugated channel structures 104 using one or more implant steps in conjunction with appropriate masking and photolithography processes before STI and gate formation. As will be set forth further below, a back gate (BG) region as well as double-diffused well (DWELL) regions (not shown in this Figure) may also be formed proximate to the source region 152 in some example corrugated channel structures based on additional and/or optional doping steps in some arrangements. Depending on implementation, various dopant species may be introduced into different regions of the corrugated channel structures 104 using LOS and/or non-LOS implant techniques where the different regions of the corrugated channel structures 104 may be selectively masked in a multi-mask scheme involving suitable photolithography steps.

FIG. 1C illustrates an IC device portion 100C including a field plate (FP) dielectric layer 162 formed around a portion of the drift region 156 of the corrugated channel structure 104 in an example. As depicted, the FP dielectric layer 162 may be formed on three sides, e.g., side 164, side 166, and side 168, of the drift region 156. Although not shown in this Figure, a gate oxide formed over the body region 154 extends from the FP dielectric layer 162. As noted previously, the formation of FP dielectric layer 162 is optional, depending on the voltage application in which the IC device 100A is intended to be deployed. In some arrangements, the FP dielectric layer 162 may comprise a “thick” silicon oxide layer having a thickness of about 30 nanometers (nm) to 120 nm. Depending on implementation, an example gate oxide layer (not explicitly shown) formed over the body region 154 and a portion of the drift region 156 may comprise a “thin” oxide layer having a thickness of about 8 nm to 12 nm.

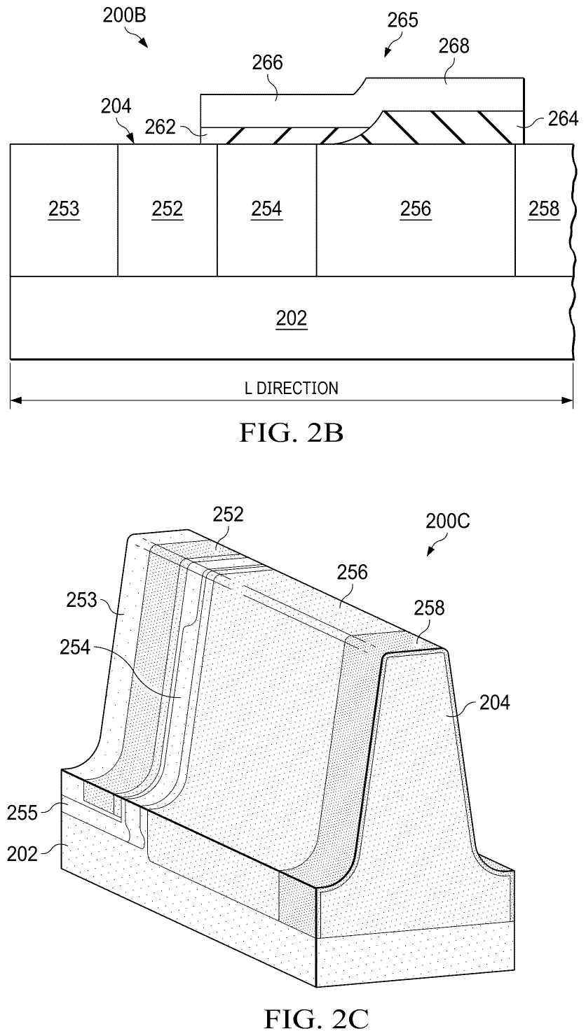

FIGS. 2A-2C depict examples that are similar to the examples set forth above, where additional aspects and features relative to an example corrugated channel structure are illustrated. In particular, FIG. 2A depicts a 3D perspective view of a corrugated channel structure 204 formed in a substrate 202 of an IC device 200A or a portion thereof, including an STI region 206 provided for isolation. The corrugated channel structure 204 includes a back gate 253 formed adjacent to a source region 252 of the corrugated channel structure 204. A drain region 258 is formed at an end opposite to the source region 252 of the corrugated channel structure 204. An electrode structure 265 comprising polysilicon or other suitable conductive material may be formed over a body region and a drift region (hidden in this view) of the corrugated channel structure 204. In some arrangements, the electrode structure 265 may include a gate 266 and a field plate 268 that are electrically isolated from the body region and the drift region of the corrugated channel structure 204 (which are disposed between the source region 252 and the drain region 258), by a “thin” gate oxide 262 and a “thick” FP oxide 264, respectively, similar to the arrangement set forth above with respect to FIG. 1C. FIG. 2B depicts a cross-sectional view 200B of the corrugated channel structure 204 through a central plane X′-X″ shown in FIG. 2A, where the body region 254 and the drift region 256 are explicitly shown. In some arrangements, the body region 254 and the drift region 256 may be electrically isolated from the gate 266 and the field plate 268 by respective portions of the gate oxide 262 and the FP oxide 264. Although not shown in FIGS. 2A and 2B, a drain-tied field plate may also be optionally formed in some additional and/or alternative examples. Further, the gate 266 and the field plate 268 may be electrically isolated in some additional and/or alternative examples.

Depending on implementation, various aspects and features of the example IC devices 100A/200A including the corrugated channel structures 104/204 as set forth above may be fabricated according to a FinFET fabrication flow described in U.S. Pat. Nos. 10,978,559; 11,152,506; 11,437,496; 11,508,842 and/or U.S. Patent Appl. Publ. No. 2022/0123130, each of which is incorporated by reference in its entirety for all purposes, which may be individually and/or collectively referred to as “incorporated disclosures”. Further, whereas some example devices are shown herein as having recessed oxide in the trenches, it is not a requirement for purposes of the present disclosure. Accordingly, example dopant balancing oxidation and removal schemes set forth herein may be implemented in a variety of FinFET devices as described in the present disclosure, which may be generally representative of multi-fin devices where the trench bottoms are part of the device active area.

FIG. 2C depicts a 3D perspective view 200C of an example corrugated channel structure, e.g., corrugated channel structure 204, illustrating different regions that may receive various types of dopants and suitable dopant balancing oxidation steps according to some examples of the present disclosure. In one implementation, the substrate 202 may be doped with a dopant of a first conductivity type, e.g., a p-type dopant such as boron. In one implementation, the source region 252 and the drain region 258 may be doped with a dopant of a second conductivity type, e.g., an n-type dopant such as phosphorus in an NSD implant process. In one implementation, the drift region 256 may be doped with one or more dopant species comprising phosphorus, arsenic, etc., in a drift implant process (e.g., NDRIFT implant process). In one implementation, one or more dopants of p-type and/or n-type may be introduced proximate to the source region 252 for forming a DWELL region 255 in the body 254 in a DWELL implant process. In one implementation, the back gate region 253 may be doped with a p-type dopant in a PSD implant process.

Without limitation, examples of the present disclosure may be configured to provide the following dopant concentrations and junction depths in the appropriate regions of the corrugated channel structure 204: an NSD implant process configured to dope the source and drain regions 252, 258 with phosphorus having a target concentration of about 1.0×10²¹ atoms/cm³ and a junction depth of about 80 nm to 100 nm; a first NDRIFT implant process configured to dope the drift region 256 with phosphorus having a target concentration of about 1.0×10¹⁷ atoms/cm³ and a junction depth of about 50 nm to 100 nm; a second NDRIFT implant process configured to dope the drift region 256 with arsenic having a target concentration of about 1.0× to 5.0×10¹⁶ atoms/cm³ and a junction depth of about 50 nm to 100 nm a p-type DWELL implant process configured to dope the DWELL region with boron having a target concentration of about 1.0×10¹⁸ atoms/cm³ and a junction depth of about 50 nm to 100 nm; an n-type DWELL implant process configured to dope the DWELL region with arsenic having a target concentration of about 1.0×10²⁰ atoms/cm³ and a junction depth of about 40 nm to 60 nm; and a PSD implant process configured to dope the back gate region 253 with boron having a target doping concentration of about 1.0×10²¹ atoms/cm³ and a junction depth of about 80 nm to 100 nm.

According to examples herein, any combination and/or sub-combination of the foregoing implant processes may be effectuated using LOS and/or non-LOS implant techniques, e.g., on a region-by-region basis, with respect to doping the corrugated channel structures. Subsequently, one or more dopant balancing oxidations steps may be performed, e.g., on a region-by-region basis, whereby an oxidized dopant layer having different thicknesses may be formed over the corrugated channel topography depending on the initial dopant concentrations in the various structural components thereof (e.g., the top surfaces and sidewalls of the fins and the bottom surfaces of the trenches). Thereafter, the oxidized dopant layer may be removed from the corrugated channel topography, thereby facilitating more uniform dopant distribution profiles across the channel structures regardless of whether LOS or non-LOS implant techniques were used in doping as will be set forth below.

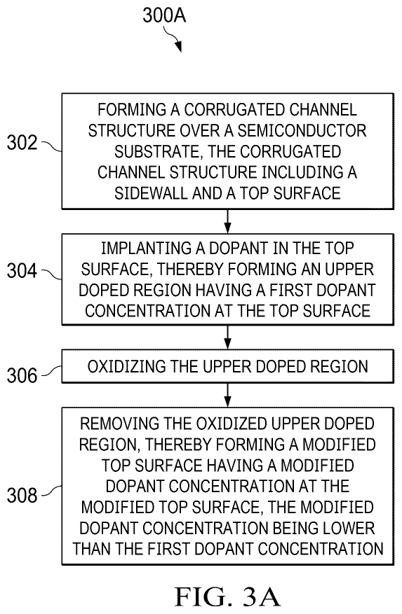

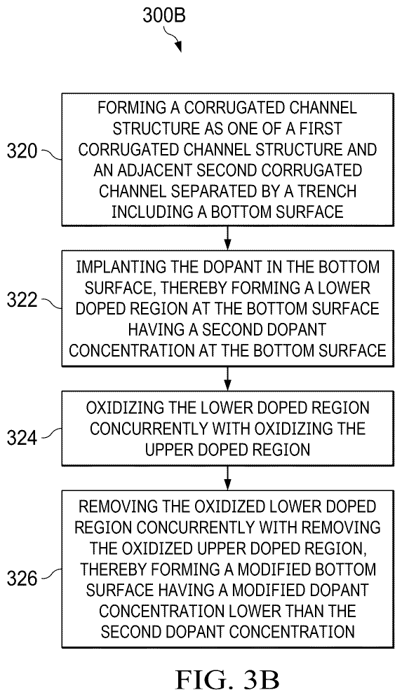

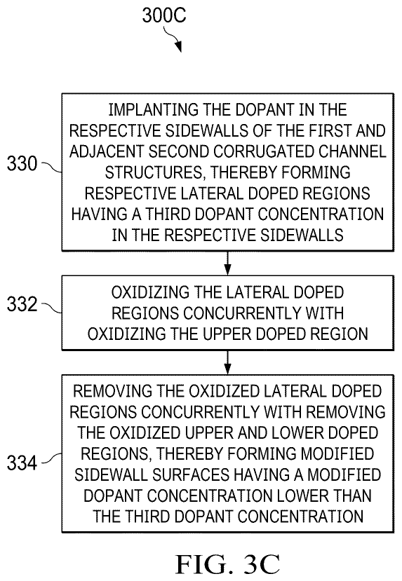

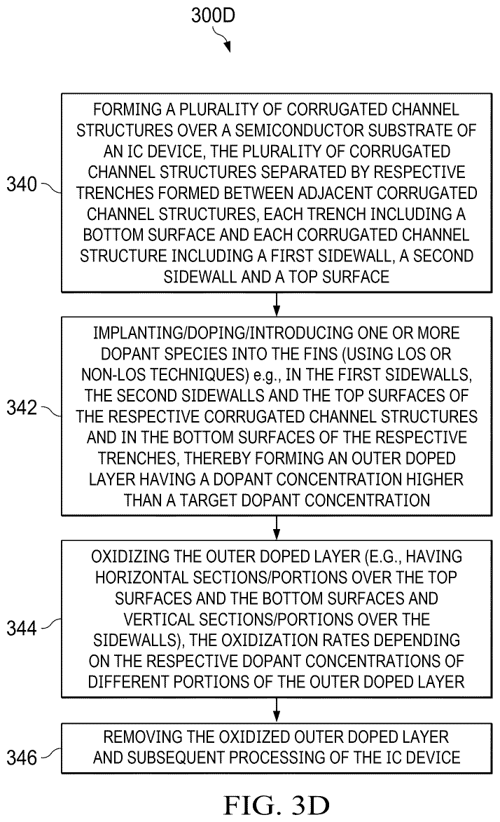

FIGS. 3A-3D are flowcharts of IC fabrication methods for conformally doping the corrugated channel structures of an IC device where the steps, blocks, acts and/or components of different flowcharts may be combined in various ways according to some examples of the present disclosure. In particular, FIG. 3A depicts a flowchart of a generalized scheme corresponding to a fabrication method 300A in an example implementation. At block 302, one or more corrugated channel structures may be formed in or over a semiconductor substrate, where a corrugated channel structure includes a sidewall, e.g., a first sidewall and a second sidewall, and a top surface. At block 304, a dopant, e.g., a first dopant, may be implanted in the top surface, thereby forming an upper doped region having a first dopant concentration at the top surface. As noted previously, the dopant may comprise n-type dopants and/or p-type dopants depending on the regional implant involved (e.g., NSD implant for the source/drain regions, etc.). At block 306, the upper doped region may be oxidized, e.g., using thermal oxidation, where the oxidation characteristics as well as the characteristics of the resulting oxidized doped material may be dependent on the dopant concentration according to some implementations. In an example, the rate of oxidation of the doped region may increase with dopant concentration, e.g., may be directly proportional to the dopant concentration. Relatedly, the thickness of the oxidized doped material may be greater than, e.g., proportional to, the dopant concentration in the doped region. In some implementations, the dopant distribution may exhibit generally a Gaussian-like profile before oxidation, indicating that the dopant concentration decreases with a distance into the silicon fin or substrate from the corresponding silicon surface. Accordingly, in an example implementation, the oxidation step may lead to a general decrease of the dopant concentration at the silicon surface, where the formed oxide absorbs the dopants from the converted silicon material. At block 308, the oxidized upper doped region may be removed, e.g., via a suitable HF wet etch, thereby forming a modified top surface having a modified dopant concentration at the modified top surface, where the modified dopant concentration is lower than the first/initial dopant concentration.

In some arrangements, the corrugated channel structure may be formed as one of a first corrugated channel structure and an adjacent second corrugated channel separated by a trench including a bottom surface as set forth at block 320 of method 300B depicted in FIG. 3B. At block 322, a dopant may be implanted in the bottom surface, e.g., concurrently with implanting the top surface or otherwise (using a LOS-based technique or a non-LOS technique, which may include a same dopant species as the first dopant or otherwise), thereby forming a lower doped region at the bottom surface having a second dopant concentration at the bottom surface. In some arrangements, the second dopant concentration at the bottom surface may be lower than the first dopant concentration at the top surface depending on the implant technique used, the aspect ratio of the corrugated channel structures, channel width, etc., among others. At block 324, the lower doped region may be oxidized concurrently with oxidizing the upper doped regions of the respective corrugated channel structures as set forth above. At block 326, the oxidized lower doped region may be removed concurrently with removing the oxidized upper doped regions, thereby forming a modified bottom surface having a modified dopant concentration lower than the second (initial) dopant concentration at the bottom surface.

Example method 300C shown in FIG. 3C is illustrative of further aspects of dopant balancing oxidation involving respective sidewalls of the corrugated channel structures set forth above. At block 330, a dopant may be implanted in the respective sidewalls of the first and adjacent second corrugated channel structures (e.g., concurrently with implanting the top/bottom surface or otherwise, using a LOS-based technique or a non-LOS technique involving a different dopant species or otherwise), thereby forming respective lateral doped regions having a third dopant concentration in the respective sidewalls. In some disclosed examples, the later doped regions may also be referred to as vertical doped regions or segments in contrast to the upper and lower doped regions set forth above, which may be referred to as horizontal doped regions or segments. At block 332, the lateral doped regions may be oxidized concurrently with oxidizing the upper/lower doped regions as previously described. At block 334, the oxidized lateral doped regions may be removed concurrently with removing the oxidized upper and lower doped regions, thereby forming modified sidewall surfaces having a modified dopant concentration lower than the third dopant concentration.

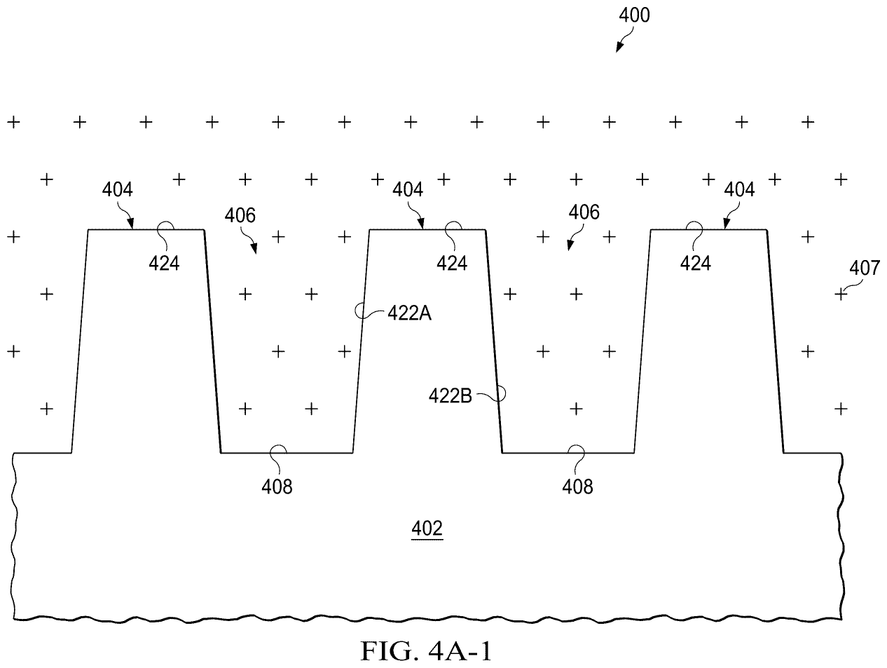

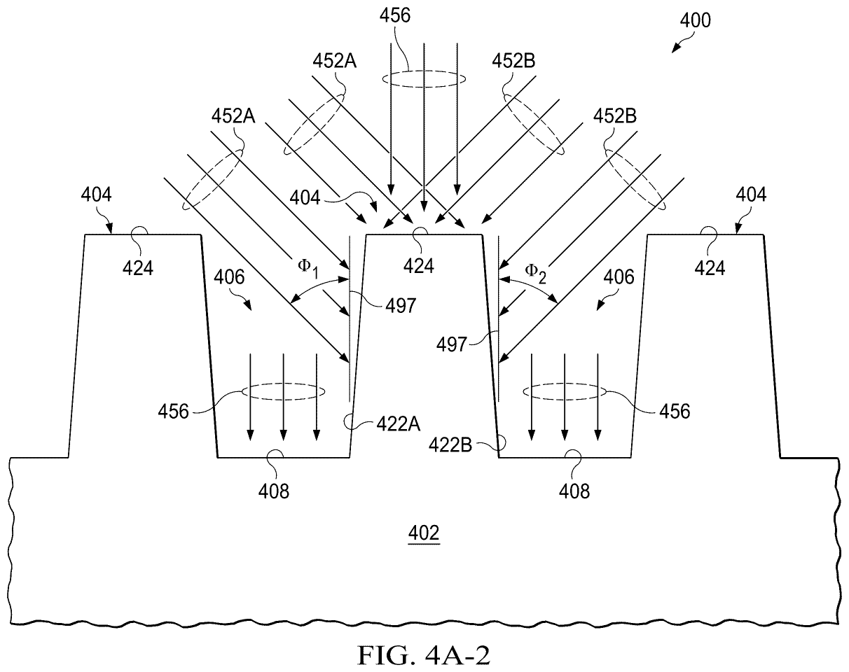

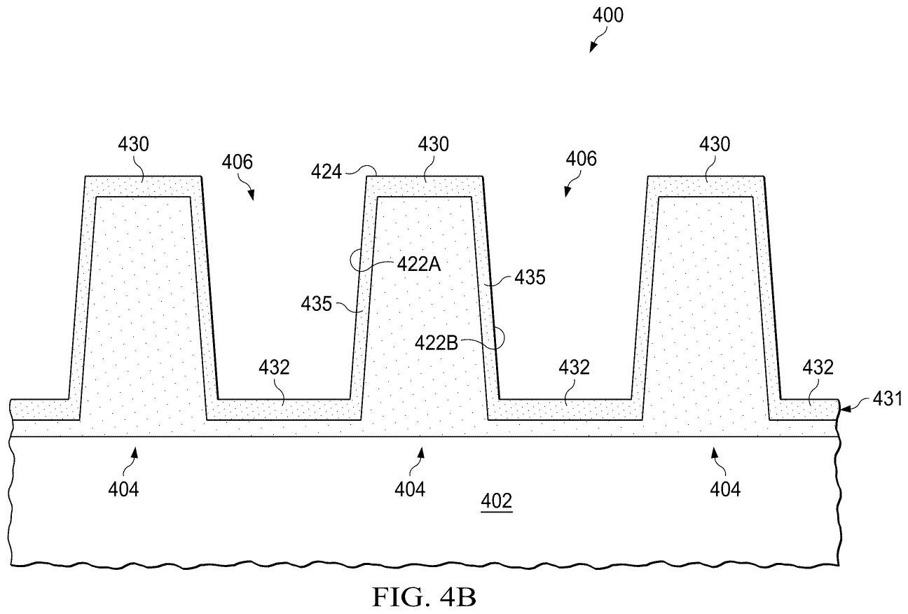

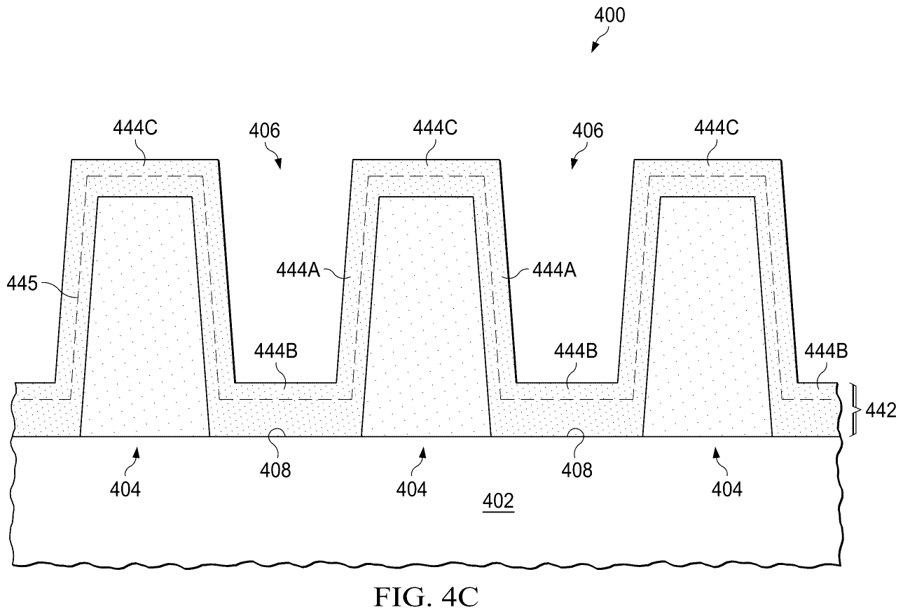

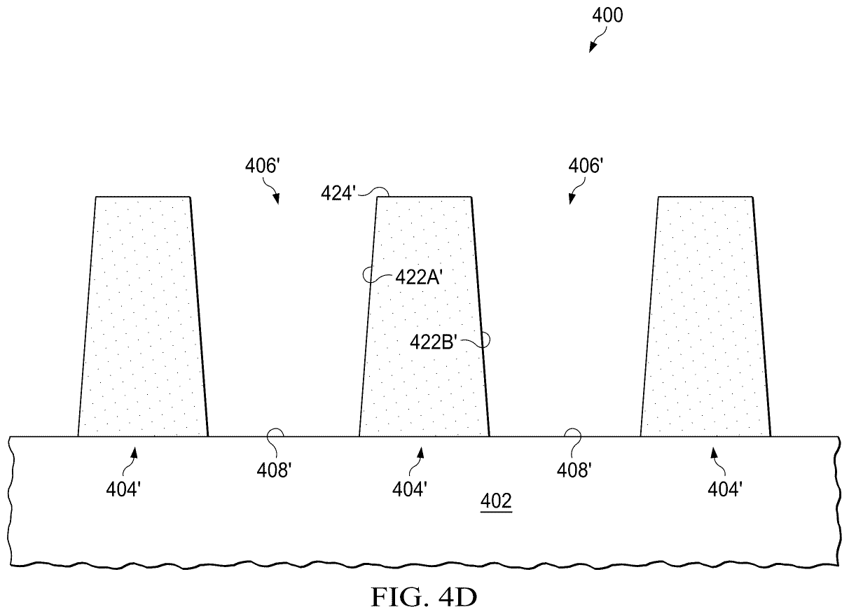

In some examples, the sidewalls and the top surfaces of the respective corrugated channel structures and the bottom surfaces of the trenches may be implanted using one or more beamline implants, which may give rise to more heavily doped upper doped regions at the top surfaces due to double dosing, as previously noted. Where the shadow effect due to the adjacent corrugated channel structures is less pronounced, e.g., due to lower aspect ratios and/or steeper implant angles relative to a surface normal of the substrate (described further below in reference to the cross-sectional view of FIG. 4A-2), the bottom surfaces may also be implanted at concentrations higher than target concentrations corresponding to the regions. On the other hand, the sidewalls of the corrugated channel structures may not receive extra or unintended dosing because of the opposite directions of the angled implants, thereby maintaining initial dopant concentrations that are closer to the target concentrations therein. Accordingly, in some examples, the oxidized upper doped regions at the top surfaces may be thicker than the oxidized lower doped regions in the trench bottom surfaces, which in turn may be thicker than the oxidized lateral doped regions formed in the sidewalls. A suitable etch process having selective removal properties may be used for stripping the oxidized doped materials from the corrugated channel topography depending on implantation, thereby achieving more uniform dopant profiles therein.

In some examples, the corrugated channel structures may be implanted using non-LOS techniques, e.g., PLAD, where there may be process variations or corners that could give rise to different doping concentrations and/or out-of-specification junction depths across the topography. Accordingly, it may be expected that different regions of the corrugated channel structures may form oxidized doped portions that have different thicknesses, which may also be removed via suitable etch processes.

FIG. 3D depicts an IC fabrication method 300D according to some examples. At block 340, a plurality of corrugated channel structures may be formed in or over a semiconductor substrate of the IC device, where the plurality of corrugated channel structures are separated from each other by respective trenches formed between adjacent corrugated channel structures. As described previously, each trench includes a bottom surface and each corrugated channel structure includes a first sidewall, a second sidewall and a top surface. At block 342, one or more dopants may be implanted in the first sidewalls, the second sidewalls and the top surfaces of the respective corrugated channel structures and in the bottom surfaces of the respective trenches, thereby forming an outer doped layer having a dopant concentration higher than a target dopant concentration. In some arrangements, the outer doped layer may be comprised of continuously connected horizontal portions formed at the top surfaces and the bottom surfaces, with vertical portions formed in the respective sidewalls that are disposed therebetween, where different portions may have different thicknesses/depths and/or dopant concentrations. At block 344, the outer doped layer may be oxidized using a suitable oxidation process, where the horizontal portions and the vertical portions may be oxidized at different rates based on the dopant concentrations in respective horizontal and vertical portions. At block 346, the oxidized outer doped layer may be removed, thereby forming modified corrugated channel structures having target form factors and target dopant distribution profiles. In some implementations, the first and second sidewalls as well as the top and bottom surface may each be modified (due to respective material removal), although it is not a necessary requirement in some additional and/or alternative arrangements. After stripping the oxidized outer doped layer, the IC device may be processed in subsequent stages to form a functionally complete structure according to a FinFET flow.

FIGS. 4A-1/4A-2 to FIG. 4D depict cross-sectional views of an IC device 400 at various stages of formation for fabricating conformally doped corrugated channel structures based on dopant balancing oxidation and removal according to an example of the present disclosure. In particular, FIGS. 4A-1 and 4A-2 depict cross-sectional views of the IC device 400 after forming one or more fins or corrugated channel structures 404 in a semiconductor substrate 402 and implanting suitable dopants using any known or heretofore unknown non-LOS implant and LOS-based implant technologies, respectively, e.g., as set forth at blocks 302/304 of FIG. 3A, blocks 320/322 of FIG. 3B, block 330 of FIG. 3C, and/or blocks 340/342, taken in any reasonable combination, as described above. In some implementations, the IC device 400 may be implanted using one or more PLAD techniques (as an example of non-LOS implant technique) or one or more beamline implant techniques (as an example of LOS-based technique), without limitation, where different types of dopant species may be implanted in different regions of the corrugated channel structures 404 (e.g., NDRIFT, PSD/NSD, DWELL, etc.). Regardless of the particular implant techniques used, dopant balancing oxidation and subsequent removal of oxidized doped regions may be implemented according to the examples herein. Whereas the semiconductor substrate 402 may predominantly comprise suitably doped silicon as substrate material in some examples, other semiconductor materials such as, Ge, SiGe, GaAs, SiC, GaN, other Group III-V materials, etc., may be used in some implementations, as noted previously, where one or more epitaxial layers or single-crystal layers may be formed or provided as part of the semiconductor substrate 402 in some arrangements. In some examples, the semiconductor substrate 402 may be part of a larger semiconductor substrate (which may include other electronic circuitry and components, not shown in the Figures) that is suitably doped depending on the type of FinFET to be fabricated in the semiconductor substrate 402. Depending on application, an example FinFET implementation may be based on a variety of technologies and may comprise a device including analog, digital and/or mixed signal device designs that may be fabricated using at least a portion of a process flow disclosed in the “incorporated disclosures” cited in this present disclosure. In some examples, a combination of semiconductor technologies may be implemented, where different technologies suitable for respective types of product design may be integrated within the same chip or IC device, e.g., linear BiCMOS or LBC (a bipolar-CMOS combination technology where MOS and bipolar technology may be used for analog functions and CMOS may be used for digital logic design), BCD (a bipolar-CMOS-DMOS combination technology where DMOS may be integrated within the IC device for power and high-voltage portions that also has analog and digital portions), and the like. Accordingly, without being limited to a particular implementation or technology node, the semiconductor substrate 402 may comprise a portion of a semiconductor process wafer, e.g., an IC die, that may be processed to include to any combination of epitaxial layers, buried layers, laterally diffused extensions, N-wells, P-wells, deep wells, shallow wells, reduced surface field (RESURF) layers formed over the dielectric layers of SOI substrates, etc. Further, the example semiconductor substrate 402 may include various isolation structures for dielectrically isolating the constituent layers, regions, well structures, etc., using a variety of isolation techniques, e.g., shallow trench isolation (STI), local oxidation of silicon (LOCOS), etc., not shown herein for the sake of clarity, which may be formed at or during any suitable front-end-of-line (FEOL) stage(s) integrated within a flow as set forth herein. Likewise, thermal oxide layers, nitride hard mask layers, etc. that may be provided as part of a FinFET fabrication flow are not specifically shown in the cross-sectional view of the drawing Figures.

The corrugated channel structures 404 may be separated by respective troughs or trenches 406 formed between adjacent corrugated channel structures 404, where the trenches 406 having bottom surfaces 408 may be formed by an RIE process as noted previously. Similar to the examples described in the foregoing sections, the corrugated channel structures 404 may each have a top surface 424 and two side walls 422A, 422B. As shown in FIG. 4A-1, dopant species 407 having appropriate energy and dosage (generated by an RF ion source, not shown in this Figure) may be applied in a PLAD implant to the various surfaces of the corrugated channel structures 404 and the trenches 406, which may or may not result in a desired target dopant profile across the channel topography as previously noted (e.g., as set forth at block 342). With respect to a LOS-based implanting scheme, the IC device 400 may be implanted using one or more beamline implants, which may comprise angled beamline implants 452A, 452B as well as vertical implants 456, as shown in FIG. 4A-2. In the disclosed examples, the angled beamline implants 452A/452B and/or the vertical implants 456 may be performed in various combinations and/or sequences, with or without surface masking for effectuating selective implanting of the different surfaces of the topography in an attempt to achieve uniform dopant concentration profiles (e.g., as set forth at block 342). In some arrangements, the sidewalls 422A, 422B of the corrugated channel structures 404 may be doped with one or more dopant species using the angled beamline implants 452A, 452B at suitable tilt angles, ϕ₁, ϕ₂, e.g., 4⁰ to 10⁰, with respect to a surface normal 497 of the semiconductor substrate 402. Additional details regarding an example beamline implant process are described in U.S. patent application Ser. No. 18/496,697, filed Oct. 27, 2023, which is incorporated by reference herein for all purposes. Additional details regarding selectively implanting different regions of corrugated channel structures using different masking schemes are described in in U.S. patent application Ser. No. 18/391,307, filed Dec. 20, 2023, which is incorporated by reference herein for all purposes.

FIG. 4B depicts a stage where an outer doped layer 431 is formed over the corrugated channel topography of the IC device 400 after the implanting stage(s) shown in FIGS. 4A-1/4A-2, e.g., prior to dopant activation. As described previously, the top surfaces 424 and the bottom surfaces 408 may be doped more heavily than the sidewalls 422A, 422B. Accordingly, different portions of the outer doped layer 431 may have a dopant concentration higher than a target dopant concentration in the topography's inner regions including the substrate material under the trench bottom surfaces 408. As illustrated, the outer doped layer 431 may comprise doped horizontal portions or segments 430 (also referred to as upper doped regions in some examples) formed at or in the top surfaces 424, doped horizontal portions or segments 432 (also referred to as lower doped regions in some examples) formed at or in the bottom surfaces 408, and doped vertical portions or segments 435 (also referred to as lateral doped regions in some examples) formed at or in the sidewalls 422A, 422B.

FIG. 4C depicts a dopant balancing oxidation stage where the outer doped layer 431 has been oxidized, thereby forming an oxidized outer doped layer 442 comprising respective oxidized vertical doped regions or segments 444A, oxidized upper doped regions or segments 444C, and oxidized lower doped regions or segments 444B (e.g., as set forth at blocks 306, 324, 332 and/or 344 above). As described previously, the thickness of the oxidized outer doped layer 442 may not be uniform and different portions or segments thereof may have different thicknesses depending on the respective dopant concentrations therein. As the outer doped material is consumed in the balancing oxidation process, the corrugated channel topography may be modified, e.g., resulting in narrower fins, wider trenches, etc., relative to the initial topography, as highlighted by a dashed contour 445 in FIG. 4C. FIG. 4D depicts the IC device 400 after removing the oxidized outer doped layer 442, e.g., by a wet etch using HF, as described previously in reference to block 308 in combination with blocks 326, 334 and/or 346, where modified corrugated channel structures 404′ having modified top surfaces 424′, modified sidewalls 422A′, 422B′ as well as modified trenches 406′ having modified bottom surfaces 408′ are illustrated, which may be expected to have suitable target dopant distribution profiles.

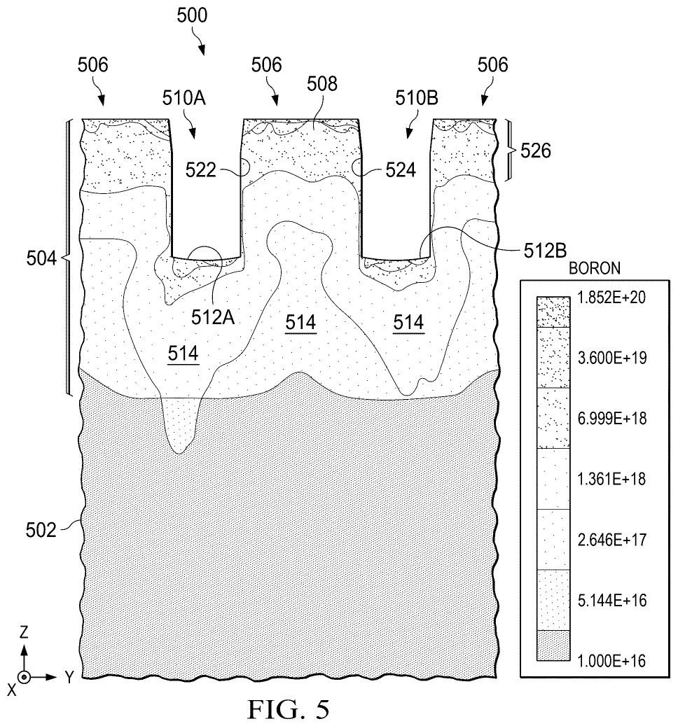

FIG. 5 depicts a simulated dopant profile across a portion of an IC device 500 including one or more corrugated channel structures 506, which may be representative of the example devices 100A, 200A, 400 described above, where an example device may be illustrative of a variety of multi-fin FET devices as previously described. By way of illustration, the IC device 500 includes a semiconductor substrate 502 having a corrugated top portion 504 comprising corrugated channel structures 506, each having a body 508 with an upper portion 526 and lateral sidewall portions 522 and 524, that are separated by respective trenches, e.g., trenches 510A, 510B. A p-type dopant, e.g., boron, may be implanted using any baseline implant process and balanced by forming an oxidized outer doped layer and subsequently removing the oxidized outer doped layer in a simulated process flow. As can be seen from FIG. 5, a substantially uniform dopant profile may be obtained across the topography of the corrugated channel structures 506, e.g., across a width of the body 508 along a horizontal axis (e.g., Y-axis) parallel to a horizontal surface of the substrate 502. Additionally, substantially uniform dopant profiles are also seen near the bottoms 512A, 512B of the trenches 510A, 510B as well as substrate regions 514 underlying the corrugated channel structures 606. As used herein, the term “substantially uniform” may be used to refer to ±1/2 one order of magnitude, or otherwise as illustrated in the example of FIG. 5.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, LPCVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride. Still further, whereas example FinFETs are depicted with subsurface fins, e.g., where the fins are formed by etching into a substrate for creating trenches that separate the resulting fins, aspects of the present disclosure may also be implemented in other FinFET architectures, e.g., including where the fins are formed or grown over a substrate as a set of protruding fins extending from the substrate's surface.

In at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A method of fabricating an integrated circuit (IC), comprising:
forming a corrugated channel structure over a semiconductor substrate, the corrugated channel structure including a sidewall and a top surface;
implanting a dopant in the top surface, thereby forming an upper doped region having a first dopant concentration at the top surface;
oxidizing the upper doped region; and
removing the oxidized upper doped region, thereby forming a modified top surface having a modified dopant concentration at the modified top surface, the modified dopant concentration being lower than the first dopant concentration.

2. The method as recited in claim 1, wherein the corrugated channel structure is one of a first corrugated channel structure and an adjacent second corrugated channel structure separated by a trench including a bottom surface, and further comprising:
implanting the dopant in the bottom surface, thereby forming a lower doped region at the bottom surface having a second dopant concentration at the bottom surface;
oxidizing the lower doped region concurrently with oxidizing the upper doped region; and
removing the oxidized lower doped region concurrently with removing the oxidized upper doped region, thereby forming a modified bottom surface having a modified dopant concentration lower than the second dopant concentration.

3. The method as recited in claim 2, further comprising:
implanting the dopant in the respective sidewalls of the first and adjacent second corrugated channel structures, thereby forming respective lateral doped regions having a third dopant concentration in the respective sidewalls;
oxidizing the lateral doped regions concurrently with oxidizing the upper doped region; and
removing the oxidized lateral doped regions concurrently with removing the oxidized upper and lower doped regions, thereby forming modified sidewall surfaces having a modified dopant concentration lower than the third dopant concentration.

4. The method as recited in claim 3, wherein the sidewalls and the top surfaces of the respective corrugated channel structures and the bottom surface of the trench are implanted using one or more beamline implants.

5. The method as recited in claim 3, wherein the sidewalls and the top surfaces of the respective corrugated channel structures and the bottom surface of the trench are implanted using one or more plasma-assisted doping (PLAD) implants.

6. The method as recited in claim 3, wherein the first dopant concentration in the top surfaces is greater than the second dopant concentration in the bottom surface.

7. The method as recited in claim 3, wherein the second dopant concentration in the bottom surface is greater than the third dopant concentration in the respective sidewalls.

8. The method as recited in claim 3, wherein the modified dopant concentrations in the sidewalls and the top surfaces of the respective corrugated channel structures and in the bottom surface of the trench correspond to a respective target dopant concentration.

9. The method as recited in claim 8, wherein the dopant is boron for forming a DWELL region in the IC and the corresponding target doping concentration is about 1.0×10¹⁸ atoms/cm³.

10. The method as recited in claim 8, wherein the dopant is arsenic for forming a DWELL region in the IC and the corresponding target doping concentration is about 1.0×10²⁰ atoms/cm³.

11. The method as recited in claim 8, wherein the dopant is phosphorus for forming an NDRIFT region in the IC and the corresponding target doping concentration is about 1.0×10¹⁷ atoms/cm³.

12. The method as recited in claim 8, wherein the dopant is phosphorus comprising an NSD implant for forming a source region in the IC and the corresponding target doping concentration is about 1.0×10²¹ atoms/cm³.

13. The method as recited in claim 8, wherein the dopant is phosphorus comprising an NSD implant for forming a drain region in the IC and the corresponding target doping concentration is about 1.0×10²¹ atoms/cm³.

14. The method as recited in claim 8, wherein the dopant is boron comprising a PSD implant for forming a back gate region in the IC and the corresponding target doping concentration is about 1.0×10²¹ atoms/cm³.

15. The method as recited in claim 3, wherein the upper doped regions, the lower doped region and the lateral doped regions are oxidized at a rate proportional to the respective dopant concentrations.

16. A method of fabricating an integrated circuit (IC), comprising:
forming a plurality of corrugated channel structures over a semiconductor substrate, the plurality of corrugated channel structures separated by respective trenches formed between adjacent corrugated channel structures, each trench including a bottom surface and each corrugated channel structure including a first sidewall, a second sidewall and a top surface;
implanting a dopant in the first sidewalls, the second sidewalls and the top surfaces of the respective corrugated channel structures and in the bottom surfaces of the respective trenches, thereby forming an outer doped layer having a dopant concentration higher than a target dopant concentration;
oxidizing the outer doped layer; and
removing the oxidized outer doped layer, thereby forming modified first sidewalls, modified second sidewalls and modified top surfaces of the respective corrugated channel structures and modified bottom surfaces of the respective trenches.

17. The method as recited in claim 16, wherein the oxidized outer doped layer is removed in a wet etch.

18. The method as recited in claim 16, wherein the first and second sidewalls and the top surfaces of the respective corrugated channel structures and the bottom surfaces of the respective trenches are implanted using one or more beamline implants.

19. The method as recited in claim 16, wherein the first and second sidewalls and the top surfaces of the respective corrugated channel structures and the bottom surfaces of the respective trenches are implanted using one or more plasma-assisted doping (PLAD) implants.

20. The method as recited in claim 16, wherein the outer doped layer is comprised of continuously connected horizontal portions formed at the top surfaces and the bottom surfaces and vertical portions formed in the respective sidewalls, and wherein the horizontal portions and the vertical portions are oxidized at different rates based on the dopant concentrations in respective horizontal and vertical portions.
